(19) United States
(12) Patent Application Publication
(10) Pub. No.: US 2024/0213420 A1
(43) Pub. Date: Jun. 27, 2024

(54) LIGHT EMITTING UNIT AND LENS UNIT

(71) Applicant: NICHIA CORPORATION, Anan-shi (JP)

(72) Inventor: Norimasa YOSHIDA, Komatsushima-shi (JP)

(73) Assignee: NICHIA CORPORATION, Anan-shi (JP)

(21) Appl. No.: 18/540,104

(22) Filed: Dec. 14, 2023

(30) Foreign Application Priority Data
Dec. 22, 2022 (JP) 2022-205866
Jul. 7, 2023 (JP) 2023-112545

(51) Int. Cl. H01L 33/58; H01L 25/075; H01L 33/50

(52) U.S. Cl. CPC H01L 33/58; H01L 25/0753; H01L 33/507

(57) ABSTRACT

A light emitting unit includes: a substrate; a light source disposed on the substrate and having a light emitting surface; and a lens unit including: a lens disposed above the light source, and an optical member fixed to the lens and disposed between the light source and the lens, the optical member including: a first region facing the light emitting surface, and a second region provided around the first region. A light transmittance of the first region is higher than a light transmittance of the second region. The lens unit is not fixed to the substrate.

### CROSS-REFERENCE TO RELATED APPLICATIONS

This application is based on and claims priority to Japanese Patent Application No. 2022-205866, filed on Dec. 22, 2022, and Japanese Patent Application No. 2023-112545, filed on Jul. 7, 2023, the entire contents of which are incorporated herein by reference.

### BACKGROUND

The disclosure herein relates to a light emitting unit and a lens unit.

Light emitting modules that include light emitting elements such as light emitting diodes (LEDs) have been widely used. As such a light emitting module, for example, Japanese Patent Publication No. 2008-177964 describes a lighting device that includes a light source, a lens, and a shielding member disposed between the light source and the lens and having an opening.

However, in the configuration described in Japanese Patent Publication No. 2008-177964, when the lens is disposed away from a substrate on which the light source is disposed, there may be a possibility that the light source is deviated from the optical axis of the lens.

### SUMMARY

According to certain embodiments of the present disclosure, it is desirable to provide a light emitting unit and a lens unit in which influence of a deviation between a light source and the optical axis of a lens can be reduced when the lens is disposed away from a substrate on which the light source is disposed.

According to one embodiment of the present disclosure, a light emitting unit includes a substrate; a light source disposed on the substrate and having a light emitting surface; and a lens unit including a lens disposed above the light source, and an optical member fixed to the lens and disposed between the light source and the lens, the optical member including a first region facing the light emitting surface, and a second region provided around the first region. The first region has a light transmittance higher than a light transmittance of the second region, and the lens unit is not fixed to the substrate.

According to one embodiment of the present disclosure, a light emitting unit includes a substrate; a light source disposed on the substrate and having a light emitting surface; and a lens unit including a lens disposed above the light source, and an optical member fixed to the lens and disposed between the light source and the lens, the optical member including a first region facing the light emitting surface, and a second region provided around the first region. The first region has a light diffusivity higher than a light diffusivity of the second region. The lens unit is spaced apart from the substrate.

According to one embodiment of the present disclosure, a lens unit to be fixed to a housing of an image capturing device includes: a lens; and an optical member fixed to the lens, the optical member including a first region, and a second region provided around the first region. The first region has a light transmittance higher than a light transmittance of the second region. The lens has a shape protruding toward the optical member.

According to one embodiment of the present disclosure, a lens unit includes a lens; and an optical member fixed to the lens, the optical member including a first region, and a second region provided around an entire periphery of the first region. The first region has a light diffusivity higher than a light diffusivity of the second region.

### BRIEF DESCRIPTION OF THE DRAWINGS

Other objects and further features of the present invention will be apparent from the following detailed description when read in conjunction with the accompanying drawings, in which:

FIG. 1 is a schematic top view illustrating an example of a light emitting unit according to a first embodiment;

FIG. 2 is a schematic cross-sectional view of the light emitting unit taken through II-II of FIG. 1;

FIG. 3 is a schematic cross-sectional view of a light emitting part according to the first embodiment;

FIG. 4A is a diagram illustrating a first example of a method of manufacturing lens units included in light emitting units according to the first embodiment;

FIG. 4B is a diagram illustrating the first example of the method of manufacturing the lens units included in the light emitting units according to the first embodiment;

FIG. 4C is a diagram illustrating the first example of the method of manufacturing the lens units included in the light emitting units according to the first embodiment;

FIG. 4D is a diagram illustrating the first example of the method of manufacturing the lens units included in the light emitting units according to the first embodiment;

FIG. 5A is a diagram illustrating a second example of a method of manufacturing lens units included in light emitting units according to the first embodiment;

FIG. 5B is a diagram illustrating the second example of the method of manufacturing the lens units included in the light emitting units according to the first embodiment;

FIG. 5C is a diagram illustrating the second example of the method of manufacturing the lens units included in the light emitting units according to the first embodiment;

FIG. 6 is a schematic top view illustrating a state in which deviation in position occurs between a light source and a lens optical axis in a light emitting unit according to a comparative example;

FIG. 7 is a schematic cross-sectional view of the light emitting unit taken through VII-VII of FIG. 6;

FIG. 8 is a schematic top view illustrating a state in which deviation in position occurs between a light source and a lens optical axis in the light emitting unit according to the first embodiment;

FIG. 9 is a schematic cross-sectional view of the light emitting unit taken through IX-IX of FIG. 8;

FIG. 10 is a schematic cross-sectional view of a light emitting unit according to a first modification of the first embodiment;

FIG. 11 is a schematic cross-sectional view of a light emitting unit according to a second modification of the first embodiment;

FIG. 12 is a schematic cross-sectional view of a light emitting unit according to a third modification of the first embodiment;

FIG. 13 is a schematic cross-sectional view of a light emitting unit according to a fourth modification of the first embodiment;

FIG. 14 is a schematic top view illustrating an example of a light emitting unit according to a second embodiment;

FIG. 15 is a schematic cross-sectional view of the light emitting unit taken through XV-XV of FIG. 14;

FIG. 16 is a schematic cross-sectional view illustrating light propagation in an optical member according to a comparative example;

FIG. 17 is a schematic cross-sectional view illustrating light propagation in an optical member according to the second embodiment;

FIG. 18A is a diagram illustrating a first example of a method of manufacturing lens units included in light emitting units according to the second embodiment;

FIG. 18B is a diagram illustrating the first example of the method of manufacturing the lens units included in the light emitting units according to the second embodiment;

FIG. 18C is a diagram illustrating the first example of the method of manufacturing the lens units included in the light emitting units according to the second embodiment;

FIG. 18D is a diagram illustrating the first example of the method of manufacturing the lens units included in the light emitting units according to the second embodiment;

FIG. 19A is a diagram illustrating a second example of a method of manufacturing lens units included in light emitting units according to the second embodiment;

FIG. 19B is a diagram illustrating the second example of the method of manufacturing the lens units included in the light emitting units according to the second embodiment;

FIG. 19C is a diagram illustrating the second example of the method of manufacturing the lens units included in the light emitting units according to the second embodiment;

FIG. 20 is a schematic top view illustrating a state in which deviation in position occurs between a light source and a lens optical axis in the light emitting unit according to the second embodiment;

FIG. 21 is a schematic cross-sectional view of the light emitting unit taken through XXI-XXI of FIG. 20;

FIG. 22 is a schematic cross-sectional view of a light emitting unit according to a first modification of the second embodiment;

FIG. 23 is a schematic cross-sectional view of a light emitting unit according to a second modification of the second embodiment;

FIG. 24 is a schematic cross-sectional view of a light emitting unit according to a third modification of the second embodiment;

FIG. 25 is a schematic cross-sectional view of a light emitting unit according to a fourth modification of the second embodiment;

FIG. 26 is a schematic top view of an optical member according to a first variation; and

FIG. 27 is a schematic top view of an optical member according to a second variation.

### DETAILED DESCRIPTION

In the following description, light emitting units and lens units according to embodiments of the present disclosure will be described in detail with reference to the accompanying drawings. The following embodiments exemplify the light emitting units and the lens units to give a concrete form to the technical ideas of the present disclosure, but the invention is not limited to the described embodiments. In addition, unless otherwise specified, the dimensions, materials, shapes, relative arrangements, and the like of components described in the embodiments are not intended to limit the scope of the present disclosure thereto, but are described as examples. The sizes, positional relationships, and the like of members illustrated in the drawings may be exaggerated for clearer illustration. Further, in the following description, the same names and reference numerals denote the same or similar members, and a detailed description thereof will be omitted as appropriate. An end view illustrating only a cut surface may be used as a cross-sectional view.

In the drawings, directions may be indicated by an X-axis, a Y-axis, and a Z-axis. The X-axis, the Y-axis, and the Z-axis are orthogonal to one another. An X direction along the X-axis and a Y direction along the Y-axis indicate directions along a light emitting surface of a light emitting part included in each of the light emitting units according to the embodiments. A Z direction along the Z-axis indicates a direction orthogonal to the light emitting surface. That is, the light emitting surface of the light emitting part is parallel to the XY plane, and the Z-axis is orthogonal to the XY plane.

A direction indicated by an arrow in the X direction is referred to as a +X direction or a +X side, and a direction opposite to the +X direction is referred to as a −X direction or a −X side. A direction indicated by an arrow in the Y direction is referred to as a +Y direction or a +Y side, and a direction opposite to the +Y direction is referred to as a −Y direction or a −Y side. A direction indicated by an arrow in the Z direction is referred to as a +Z direction or a +Z side, and a direction opposite to the +Z direction is referred to as a −Z direction or a −Z side. In the embodiments, light sources included in the light emitting units are configured to emit light to the +Z side as an example. Further, the optical axes of the lens units according to the embodiments are along the Z-axis.

The term “top view” as used in the embodiments described below refers to viewing an object downwardly from the +Z side. In the embodiments described below, a surface of the object as viewed from a position located further in the +Z direction or from the +Z side is referred to as an “upper surface,” and a surface of the object as viewed from a position located further in the -Z direction or from the −Z side is referred to as a “lower surface.” However, these directions do not limit the orientations of the light emitting units and the lens units during use, and the light emitting units and the lens units may be used in any orientations. In the embodiments described below, each of “along the X-axis,” “along the Y-axis,” and “along the Z-axis” includes a case where the object is at an inclination within a range of ±10° with respect to the corresponding one of the axes. Further, in the embodiments, the term “orthogonal” may include a deviation within ±10° with respect to 90°.

Further, in the present specification and the claims, if there are multiple components and these components are to be distinguished from one another, the components may be distinguished by adding terms “first,” “second,” and the like before the names of the components. Further, objects to be distinguished may be different between the specification and the claims. Therefore, even if a component described in the claims is indicated by the same term as that in the specification, an object specified by this component is not necessarily the same between the specification and the claims.

For example, if components are distinguished by the ordinal numbers “first,” “second,” and “third” in the specification, and components with “first” and “third” or components with “first” and without a specific ordinal number in the specification are described in the claims, these components may be distinguished by the ordinal numbers “first” and “second” in the claims for ease of understanding. In this case, the components with “first” and “second” in the claims respectively refer to the components with “first” and “third” or the components with “first” and without a specific ordinal number in the specification. This rule is applied not only to components but also other objects in a reasonable and flexible manner.

In one example, each of the light emitting units according to the embodiments described below is mounted on a smartphone, and is a light emitting unit for a camera flash for an image capturing device provided in the smartphone. Examples of the image capturing device include a camera configured to capture still images and a video camera configured to capture moving images. The lens units according to the embodiments are included in the respective light emitting units.

### First Embodiment

Example of Overall Configuration of Light Emitting Unit 100

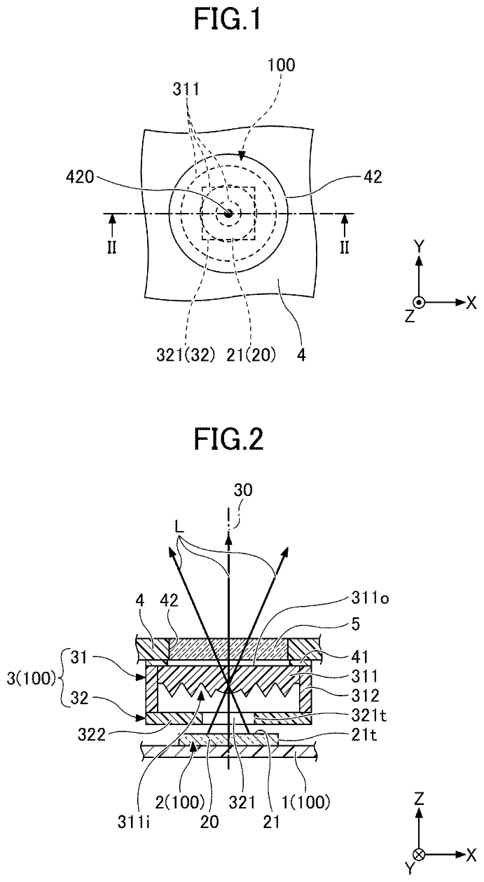

The overall configuration of a light emitting unit 100 according to a first embodiment will be described with reference to FIG. 1 and FIG. 2. FIG. 1 is a schematic top view illustrating an example of the light emitting unit 100. FIG. 2 is a schematic cross-sectional view of the light emitting unit 100 taken through II-II of FIG. 1.

In the present embodiment, the light emitting unit 100 includes a substrate 1, a light source 2, and a lens unit 3.

The substrate 1 is a substrate that includes wiring and on which the light source 2 and various electric elements can be mounted. The substrate 1 is a plate-shaped member having a substantially circular outer shape in a top view. However, the substrate 1 may have an outer shape such as substantially rectangular shape, a substantially elliptical shape, or a substantially polygonal shape in a top view.

The light source 2 includes a light emitting part 20. The light emitting part 20 is disposed on the substrate 1, and has a light emitting surface 21. In the example illustrated in FIG. 2, the light emitting part 20 is mounted on the upper surface (surface on the +Z side) of the substrate 1. The outer shape of the light emitting part 20 in a top view is a substantially rectangular shape. However, the light emitting part 20 may have an outer shape such as a substantially circular shape, a substantially elliptical shape, or a substantially polygonal shape in a top view. The light source 2 is configured to emit light from the light emitting surface 21 of the light emitting part 20 toward the lens unit 3. The number of light emitting parts 20 included in the light source 2 is not limited to one, and one or more light emitting parts 20 may be included.

The lens unit 3 includes a lens 31 and an optical member 32. The lens unit 3 is spaced apart from the substrate 1. For example, the lens unit 3 is fixed to a housing 4 of a smartphone by an adhesive member 41. The housing 4 of the smartphone is spaced apart from the substrate 1. In other words, the lens unit 3 is fixed to the housing 4 of the smartphone that is not integrated with the substrate 1 and is a member separate from the substrate 1. Therefore, the lens unit 3 is not integrated with the substrate 1 and is a member separate from the substrate 1. As used herein, a member being “separate from” another member means that, assuming that there are two members, the two members are not in contact with and are not bonded to each other, either directly or via an adhesive member or the like.

The lens 31 includes a Fresnel lens 311 and a support member 312. The lens 31 is disposed above the light source 2. The Fresnel lens 311 included in the lens 31 has a shape protruding toward the optical member 32. The outer shape of the lens 31 in a top view is a substantially circular shape. However, the lens 31 may have an outer shape such as a substantially rectangular shape, a substantially elliptical shape, or a substantially polygonal shape in a top view. The support member 312 supports the Fresnel lens 311. The support member 312 is fixed to the optical member 32, thereby fixing the lens 31 to the optical member 32.

In the present embodiment, the Fresnel lens 311 has a light exit surface 311o and a light incident surface 311i. The light exit surface 311o is substantially flat and the light incident surface 311i has a plurality of annular projections. The plurality of annular projections is preferably concentric. The Fresnel lens 311 includes a light-transmissive resin, glass, or the like. As used herein, “light-transmissive” indicates being adapted to transmit, preferably, 60% or more of the light from the light source 2. A lens optical axis 30 indicated by a dash-dot line in FIG. 2 is the optical axis of the lens unit 3. More specifically, the lens optical axis 30 is the optical axis of the

Fresnel lens 311 of the lens unit 3.

The support member 312 includes a resin, a metal, a ceramic, or the like. The Fresnel lens 311 and the support member 312 may be integrally formed by molding a resin material. Alternatively, after the Fresnel lens 311 and the support member 312 are separately formed, the Fresnel lens 311 may be secured to the support member 312 by an adhesive member or the like.

The optical member 32 is located between the lens 31 and the light source 2. Further, the optical member 32 is fixed to the lens 31, and allows the light from the light source 2 to be incident on the lens 31. The optical member 32 includes a first region 321 facing the light emitting surface 21, and a second region 322 provided around the first region 321. The light transmittance of the first region 321 is higher than the light transmittance of the second region 322. The outer shape of the first region 321 in a top view is a substantially rectangular shape, and the outer shape of the second region 322 in a top view is a substantially circular shape. That is, the outer shapes of the first region 321 and the second region 322 in a top view are different from each other. Each of the first region 321 and the second region 322 may have an outer shape such as a substantially circular shape, a substantially elliptical shape, or a substantially polygonal shape in a top view. Further, the first region 321 and the second region 322 may have the same outer shape in a top view.

The optical member 32 is a plate-shaped member including a metal, glass, a resin, or the like. FIG. 2 illustrates a configuration in which the optical member 32 is composed of one layer. In FIG. 2, the first region 321 is a light-passing portion, and is, for example, a through hole formed in the plate-shaped member. A portion of the light from the light source 2 passes through the first region 321, which is the through hole. The second region 322 is a region other than the first region 321 in the optical member 32. The second region 322 includes a light shielding portion that reflects, scatters, or absorbs a portion of the light from the light source 2 so as to shield a portion of the light. In the present embodiment, if the first region 321 is a through hole, the optical member 32 is constituted by the through hole, which is the first region 321, and the light shielding portion of the second region 322. Considering that the optical member 32 includes the first region 321, that is the through hole, i.e., an opening, the optical member 32 can be referred to as an opening member. The first region 321 is not limited to a through hole, and may be any region having a higher light transmittance than that of the second region 322. The first region 321 may be a first light-transmissive portion that transmits a portion of the light from the light source 2 and that does not include a light scattering substance. For example, a member containing a resin material, glass, or the like may be disposed in the first region 321 such that the light transmittance of the member disposed in the first region 321 is higher than the light transmittance of a member including a resin material, glass, a metal, or the like disposed in the second region 322.

The housing 4 has an opening 42. An opening center 420 in FIG. 1 is the center of the opening 42. A light-transmissive member 5 is disposed and fixed in the opening 42. Each of the opening 42 and the light-transmissive member 5 has a substantially circular shape in a top view. However, each of the opening 42 and the light-transmissive member 5 may have an outer shape such as a substantially rectangular shape, a substantially elliptical shape, or a substantially polygonal shape in a top view. The lens unit 3 is fixed to a predetermined position of the housing 4 by the adhesive member 41, such that the substantially-flat light exit surface 311o of the

Fresnel lens 311 faces the light-transmissive member 5. The lens unit 3 is disposed such that the lens optical axis 30 overlaps with the opening 42 in a top view, and the lens optical axis 30 preferably passes through the opening center 420.

As illustrated in FIG. 1, when the light emitting unit 100 is observed from above, an observer can visually recognize a portion of the optical member 32 through the opening 42 and the Fresnel lens 311. In addition, the observer can visually recognize a portion of the light emitting surface 21 of the light emitting part 20 through the first region 321 of the optical member 32.

In the present embodiment, the first region 321 is the light-passing portion that includes the through hole or the first light-transmissive portion. The second region 322 includes the light shielding portion. As illustrated in FIG. 2, an outer edge 21t of the light emitting surface 21 is located outward relative to an outer edge 321t of the first region 321. Of the light emitted from the light source 2, light that reaches the first region 321 passes through the first region 321 or is transmitted through the first region 321, and is then transmitted through the Fresnel lens 311. Then, the light transmitted through the Fresnel lens 311 is transmitted through the light-transmissive member 5, and is irradiated upward from the light-transmissive member 5 as irradiation light L. Conversely, of the light emitting from the light emitting part 20 of the light source 2, light that reaches the second region 322, which is the light shielding portion, is shielded by the second region 322. In the present specification, both light exiting a member through a through hole or the like and light exiting a member through the inside of a substance of the member may be indicated by the term “pass.” Unless otherwise specified, the term “light-passing portion” encompasses both of these meanings.

In particular, passing through the inside of the substance may be expressed as “transmitting.”

In the present embodiment, the light shielding portion may be formed of a white resin containing a light scattering substance. With the light shielding portion formed of a white resin, the light emitted from the light source 2 can be reflected by the light shielding portion, and the reflected light can pass through the first region 321. Accordingly, the light extraction of the light emitting unit 100 can be improved. The light shielding portion may be composed of a black resin containing a light absorbing substance.

In the present embodiment, the distance between the light source 2 and the optical member 32 may be 0 mm or more and 2 mm or less, and is preferably 0.01 mm or more and 2 mm or less. By setting the distance between the light source 2 and the optical member 32 to be 0 mm or more, the light from the light source 2 can efficiently pass through the first region 321 of the optical member 32. By setting the distance between the light source 2 and the optical member 32 to be 2 mm or less, the thickness of the light emitting unit 100 can be reduced.

### Example Configuration of Light Emitting Part 20

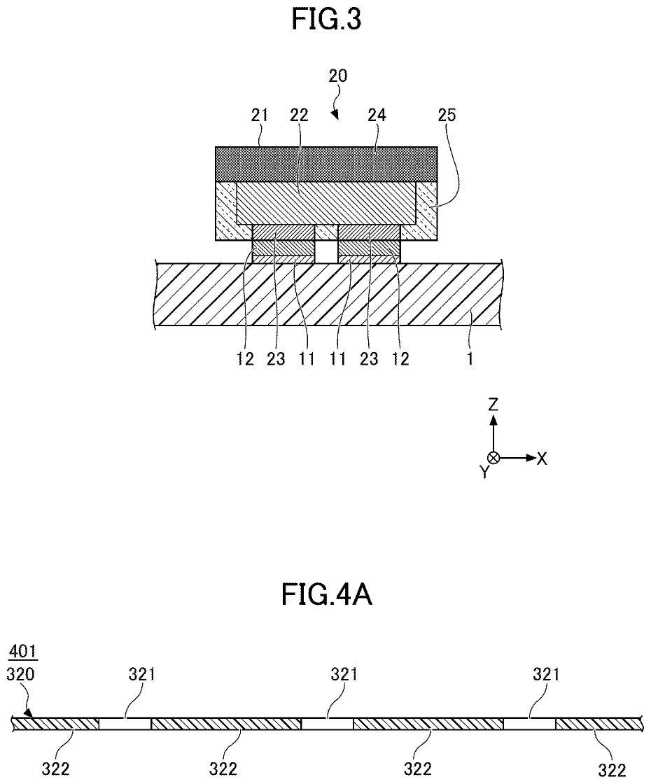

FIG. 3 is a schematic cross-sectional view of the light emitting part 20. FIG. 3 illustrates the cross-sectional view of the light emitting part 20 taken through line II-II of FIG. 1.

As illustrated in FIG. 3, the light emitting part 20 is mounted on a surface on the +Z side of the substrate 1. The surface on the +Z side of the light emitting part 20 is the light emitting surface 21, and the surface of the light emitting part 20 opposite the light emitting surface 21 is a mounting surface. The light emitting part 20 includes a light emitting element 22, a wavelength conversion member 24 disposed on the light emitting element 22, and a light shielding member 25 covering the lateral surfaces of the light emitting element 22 and the bottom surface of the wavelength conversion member 24. In the example illustrated in FIG. 3, the wavelength conversion member 24 is provided on the surface, on the +Z side, of the light emitting element 22. The light shielding member 25 covers the lateral surfaces of the light emitting element 22 and the bottom surface of the wavelength conversion member 24, except for the surface on the +Z side and the lateral surfaces of the wavelength conversion member 24. When the light source 2 includes a plurality of light emitting parts 20, wavelength conversion members 24 of adjacent light emitting parts 20 of the plurality of light emitting parts 20 may be connected together. In the light emitting part 20, the lateral surfaces of the wavelength conversion member 24 may be covered by the light shielding member 25.

When the light source 2 includes a plurality of light emitting parts 20, the light shielding member 25 may be provided between adjacent light emitting parts 20 of the plurality of light emitting parts 20, and may integrally hold a plurality of light emitting elements 22 and a plurality of wavelength conversion members 24. With this configuration, the plurality of light emitting parts 20 can be collectively mounted, and the intervals between the light emitting parts 20 can be narrowed.

At least one pair of positive and negative electrodes 23 (for example, a p-side electrode and an n-side electrode) are preferably provided on the surface of the light emitting element 22 opposite the light emitting surface 21. In the present embodiment, the outer shape of the light emitting surface 21 in a top view is a substantially rectangular shape. Alternatively, the outer shape of the light emitting surface 21 in a top view may be a substantially circular shape, a substantially elliptical shape, or a polygonal shape such as a substantially triangular shape or a substantially hexagonal shape.

The light emitting element 22 is preferably made of various semiconductors such as group III-V compound semiconductors and group II-VI compound semiconductors. As the semiconductors, nitride-based semiconductors such as InXAlYGal-X-YN (0≤X, 0≤Y, X+Y≤1) are preferably used, and InN, AlN, GaN, InGaN, AlGaN, InGaAlN, and the like can also be used. The light emitting element 22 is, for example, an LED or a laser diode (LD). The emission peak wavelength of the light emitting element 22 is preferably 400 nm or more and 530 nm or less, more preferably 420 nm or more and 490 nm or less, and even more preferably 450 nm or more and 475 nm or less, from the viewpoint of emission efficiency, excitation of a wavelength conversion substance, which will be described later, and the like.

The wavelength conversion member 24 is a member having, for example, a substantially rectangular outer shape in a top view. The wavelength conversion member 24 is disposed to cover the upper surface of the light emitting element 22. The wavelength conversion member 24 can be formed by using a light-transmissive resin material or an inorganic material such as a ceramic or glass. As the resin material, a thermosetting resin such as a silicone resin, a silicone-modified resin, an epoxy resin, an epoxy-modified resin, or a phenol resin can be used. In particular, a silicone resin having high light resistance and heat resistance or a modified resin thereof is preferable. As used herein, the term “light-transmissive” means that 60% or more of the light from the light emitting element 22 is preferably transmitted. Further, a thermoplastic resin such as a polycarbonate resin, an acrylic resin, a methylpentene resin, or a polynorbornene resin can be used for the wavelength conversion member 24. Further, the wavelength conversion member 24 contains, in the resin described above, a wavelength conversion substance that converts the wavelength of at least a portion of the light from the light emitting element 22. For example, the wavelength conversion member 24 may be a resin material, a ceramic, glass, or the like containing a wavelength conversion substance, a sintered body of a wavelength conversion substance, or the like. Further, the wavelength conversion member 24 may be a multilayer member in which a resin layer containing a wavelength conversion substance is disposed on the surface on the ±Z side of a molded body made of a resin, a ceramic, glass, or the like.

Examples of a wavelength conversion substance contained in the light transmissive member 24 include yttrium aluminum garnet based phosphors (for example,(Y,Gd)3(Al,Ga)5O12:Ce), lutetium aluminum garnet based phosphors (for example, Lu3(Al,Ga) 5O12:Ce), terbium aluminum garnet based phosphors (for example, Tb3(Al,Ga)5O12:Ce), CCA based phosphors (for example, Ca10(PO4)6C12:Eu), SAE based phosphors (for example, Sr4Al14O25:Eu), chlorosilicate based phosphors (for example, Ca8MgSi4O16Cl2:Eu), silicate based phosphors (for example, (Ba,Sr,Ca,Mg)2SiO4:Eu), oxynitride based phosphors such as β-SiAlON based phosphors (for example, (Si,Al)3(O,N)4:Eu) and α-SiAlON based phosphors (for example, Ca(Si,Al)12(O,N)16:Eu), nitride based phosphors such as LSN based phosphors (for example, (La,Y)3Si6N11:Ce), BSESN based phosphors (for example, (Ba,Sr)2Si5N8:Eu), SLA based phosphors (for example, SrLiAl3N4:Eu), CASN based phosphors (for example, CaAlSiN3:Eu), and SCASN based phosphors (for example, (Sr,Ca)AlSiN3:Eu), fluoride based phosphors such as KSF based phosphors (for example, K2SiF6:Mn), KSAF based phosphors (for example, K2(Si1-xAlx)F6-x:Mn, where x satisfies 0<x<1), and MGF based phosphors (for example, 3.5MgO·0.5MgF2·GeO2:Mn), quantum dots having a Perovskite structure (for example, (Cs,FA,MA)(Pb,Sn)(F,Cl,Br,I)3, where FA and MA represent formamidinium and methylammonium, respectively), II-VI quantum dots (for example, CdSe), III-V quantum dots (for example, InP), and quantum dots having a chalcopyrite structure (for example, (Ag,Cu)(In,Ga)(S,Se)2). The wavelength conversion substances described above are particles. One of these wavelength conversion substances may be used alone, or two or more of these wavelength conversion substances may be used in combination.

In the present embodiment, the light emitting part 20 uses a blue light emitting element as the light emitting element 22. The wavelength conversion member 24 includes a wavelength conversion substance that converts the wavelength of the light emitted from the light emitting element 22 into the wavelength of yellow, so that the light emitting part 20 emits white light. As a light scattering substance contained in the wavelength conversion member 24, titanium oxide, barium titanate, aluminum oxide, silicon oxide, or the like can be used.

The light shielding member 25 is a member that covers the lateral surfaces of the light emitting element 22 and the bottom surface of the wavelength conversion member 24. The light shielding member 25 directly or indirectly covers the surfaces of the light emitting element 22 and the bottom surface of the wavelength conversion member 24. With this configuration, light leaking from the lateral surfaces of the light emitting element 22 and the bottom surface of the wavelength conversion member 24 is reduced, which allows for improving the extraction efficiency of the light emitted from the light emitting element 22. The upper surface of the wavelength conversion member 24 is exposed from the light shielding member 25, and serves as the light emitting surface 21 of the light emitting part 20. When the light source 2 includes a plurality of light emitting parts 20, light shielding members 25 may be spaced apart from each other between adjacent ones of the plurality of light emitting parts 20. To improve the light extraction efficiency, the light shielding member 25 is preferably composed of a member having a high light reflectance. For example, a resin material containing a light scattering substance such as a white pigment can be used for the light shielding member 25.

Examples of the light scattering substance include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. It is preferable to use one of these substances alone or a combination of two or more of these substances. Further, as the resin material, it is preferable to use a base material containing a resin material whose main component is a thermosetting resin such as an epoxy resin, an epoxy-modified resin, a silicone resin, a silicone-modified resin, or a phenol resin.

The light emitting part 20 is electrically connected to wiring 11 of the substrate 1. The substrate 1 preferably includes the wiring 11 disposed on a surface of the substrate 1. The substrate 1 may include the wiring 11 inside the substrate 1. The light emitting part 20 and the substrate 1 are electrically connected to each other by connecting the wiring 11 of the substrate 1 to at least a pair of positive and negative electrodes 23 of the light emitting part 20 via electrically-conductive adhesive members 12. The configuration, the size, and the like of the wiring 11 of the substrate 1 are set in accordance with the configuration, the size, and the like of the electrodes 23 of the light emitting part 20.

For a base material of the substrate 1, an insulating material, a material that does not easily transmit light emitted from the light emitting part 20, external light, or the like, and a material having a certain strength are preferably used. Specifically, the substrate 1 can include, as a base material thereof, a ceramic such as alumina, aluminum nitride, mullite, or silicon nitride, or a resin such as a phenol resin, an epoxy resin, a polyimide resin, a bismaleimide triazine resin (BT resin), polyphthalamide, or a polyester resin.

The wiring 11 can be composed of at least one of copper, iron, nickel, tungsten, chromium, aluminum, silver, gold, titanium, palladium, rhodium, an alloy thereof, and the like. In addition, a layer of silver, platinum, aluminum, rhodium, gold, an alloy thereof, or the like may be provided on the surface layer of the wiring 11 considering wettability and/or light reflectivity of the electrically-conductive adhesive members 12.

### Examples of Methods of Manufacturing Lens Units 3

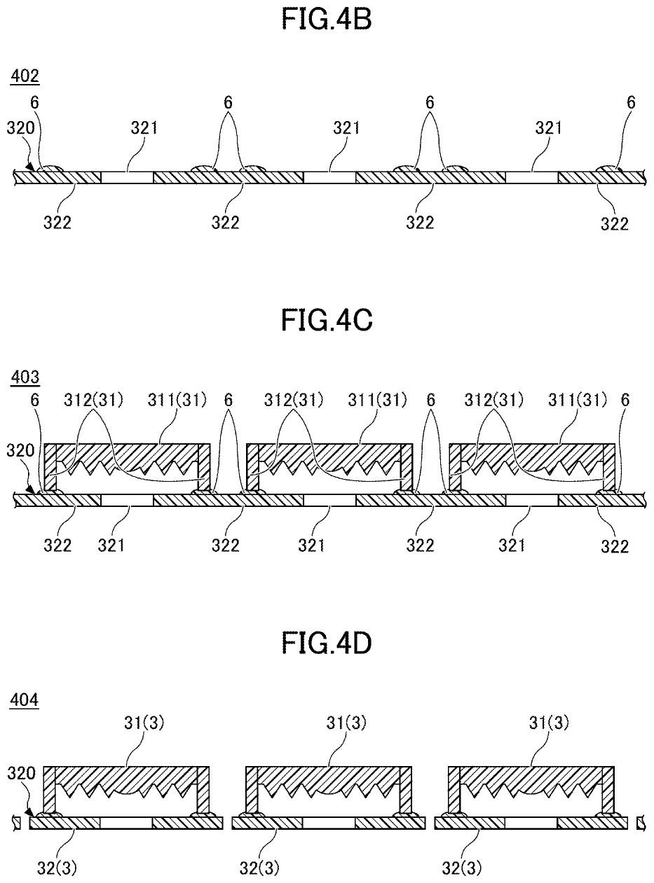

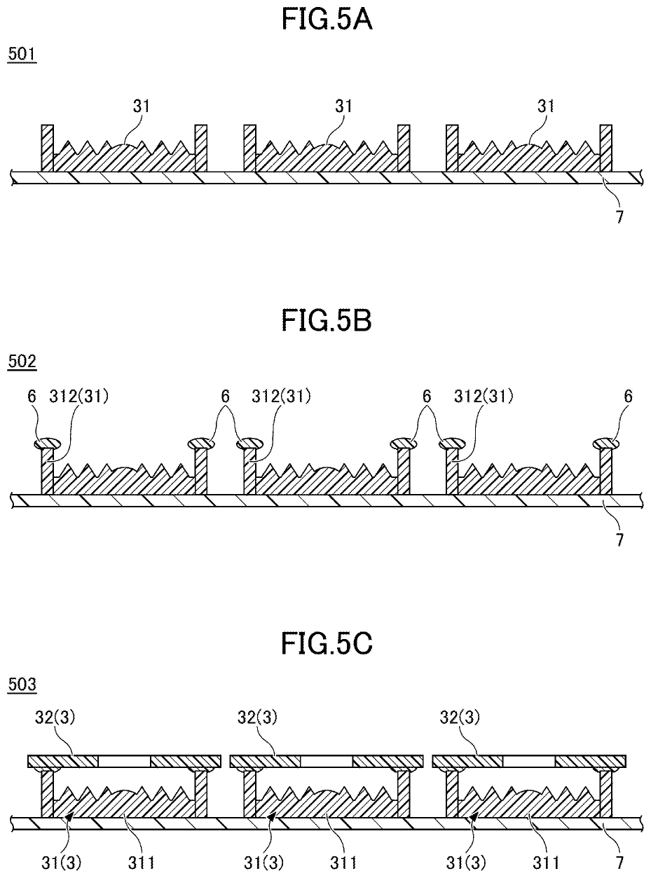

Methods of manufacturing lens units 3 included in light emitting units 100 will be described with reference to FIG. 4A through FIG. 4D and FIG. 5A through FIG. 5C. FIG. 4A through FIG. 4D are diagrams illustrating a first example of a method of manufacturing lens units 3. FIG. 5A through FIG. 5C are diagrams illustrating a second example of a method of manufacturing lens units 3.

### First Example

As illustrated in FIG. 4A, FIG. 4B, FIG. 4C, and FIG. 4D, the method of manufacturing lens units 3 according to the first example includes a first step 401, a second step 402, a third step 403, and a fourth step 404.

The first step 401 is a step of providing a base 320 in which a plurality of first regions 321 arranged one-dimensionally or two-dimensionally is formed. In the example illustrated in FIG. 4A through FIG. 4D, three first regions 321 arranged one-dimensionally are formed in the base 320. Regions other than the first regions 321 in the base 320 correspond to second regions 322. In the present specification, the term “providing the base 320” includes manufacturing the base 320, obtaining the base 320 by, e.g., purchasing the base 320, and the like.

For example, the base 320 is a plate-shaped member including a metal, a resin, or the like. Each of the first regions 321 is a through hole formed in the base 320. When the base 320 includes a metal, the first regions 321, which are through holes, are formed by subjecting the base 320 to punching, etching, cutting, or the like. When the base 320 includes a resin, the base 320 can be produced by forming through holes and subsequently disposing the resin in the through holes, or can be produced by molding or the like. Conversely, if the first regions 321 are not through holes but regions including a resin having a higher light transmittance than that of the second regions 322, the base 320 can be formed by, for example, double-molding of resins.

The first regions 321 are formed of a resin having a higher light transmittance than that of the second regions 322.

The base 320 may be configured to include a light-transmissive resin, glass, or the like. Alternatively, the base 320 may be configured to include a resin, glass, a sintered body, or the like having light transmissivity and containing a light scattering substance or a wavelength conversion substance. A white resin containing a light scattering substance such as titanium oxide or a black resin containing a light absorbing substance such as carbon black may be disposed in the second regions 322 of the base 320. In this case, preventing the above-described white resin or black resin from being disposed in the first regions 321 of the base 320 allows the light transmittance of the first regions 321 to be higher than the light transmittance of the second regions 322.

The second step 402 is a step of disposing adhesive members 6 on the base 320. For example, when each of the adhesive members 6 is a liquid resin, the adhesive members 6 are applied onto a plurality of predetermined positions of the second regions 322 of the base 320 by using a mechanism or the like that can discharge the adhesive members 6. Each of the adhesive members 6 may be a double-sided tape.

The third step 403 is a step of fixing lenses 31 to the base 320. In the third step 403, before hardening of the resin, serving as the adhesive members 6 and applied to the second regions 322 of the base 320, is completed, the lenses 31 are disposed on the base 320 such that support members 312 of the lenses 31 are in contact with the adhesive members 6. The lenses 31 are disposed on the base 320, each corresponding to a respective one of the first regions 321, such that the center of each of the first regions 321 substantially faces the center of a respective one of the Fresnel lenses 311. After the lenses 31 are disposed on the base 320, hardening of the resin serving as the adhesive members 6 is completed, so that the lenses 31 are fixed to the base 320. For the adhesive members 6, an air-setting member or a member that sets by being irradiated with energy rays such as heat or ultraviolet light may be used.

The fourth step 404 is a step of cutting into a plurality of lens units 3 from the base 320 by cutting the base 320. Regions of the base 320 that are located outward of the lenses 31 are cut into the plurality of lens units 3 from the base 320 by dicing, laser processing, or the like. In the example illustrated in FIG. 4A through FIG. 4D, three lens units 3 are obtained by cutting.

In this manner, the lens units 3 can be manufactured by the manufacturing method according to the first example.

### Second Example

As illustrated in FIG. 5A, FIG. 5B, and FIG. 5C, the method of manufacturing lens units 3 according to the second example includes a first step 501, a second step 502, and a third step 503.

The first step 501 is a step of mounting a plurality of lenses 31 on a base 7. The lenses 31 are mounted on the base 7 such that the light exit side of each of the lenses 31, specifically, the light exit surface of each of Fresnel lenses 311 faces the base 7. In the example illustrated in FIG. 5A through FIG. 5C, three lenses 31 are arranged one-dimensionally on the base 7.

The second step 502 is a step of disposing adhesive members 6 on support members 312 of the plurality of lenses 31. The adhesive members 6 are disposed on end portions of the support members 312, which are located on the light incident side of the lenses 31. That is, the adhesive members 6 are disposed on portions of the support members 312 at a side opposite from the base 7. For example, when each of the adhesive members 6 is a liquid resin, the adhesive members 6 are applied by using a mechanism or the like that can discharge the adhesive members 6. Each of the adhesive members 6 may be a double-sided tape.

The third step 503 is a step of fixing optical members 32 to the lenses 31. In the third step 503, before hardening of the resin, serving as the adhesive members 6 and applied to the support members 312, is completed, the optical members 32 are disposed on the lenses 31 such that the optical members 32 contact the adhesive members 6. Each of the optical members 32 is disposed on a respective one of the lenses 31 such that the center of each of the Fresnel lenses 311 faces the center of a respective one of first regions 321. After the optical members 32 are disposed, hardening of the resin serving as the adhesive members 6 is completed, so that the optical members 32 are fixed to the respective lenses 31. Subsequently, the lenses 31 are separated from the base 7 to obtain lens units 3.

In this manner, the lens units 3 can be manufactured by the manufacturing method according to the second example.

### Main Effects of Lens Unit 3 and Light Emitting Unit 100

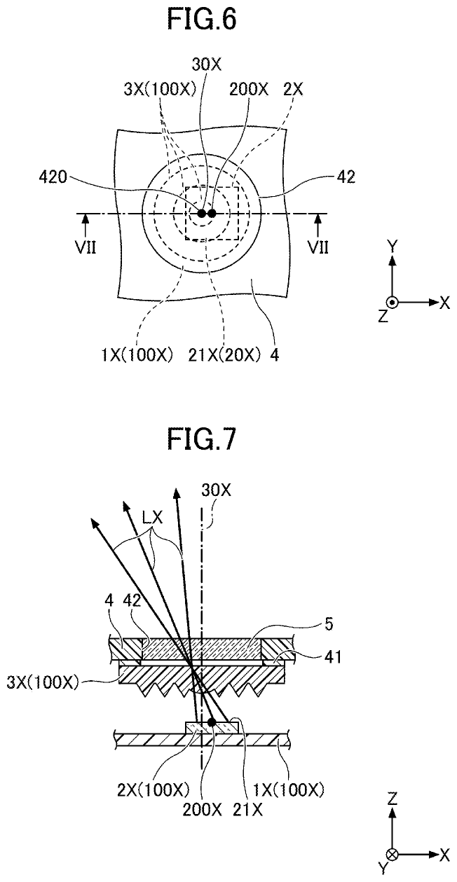

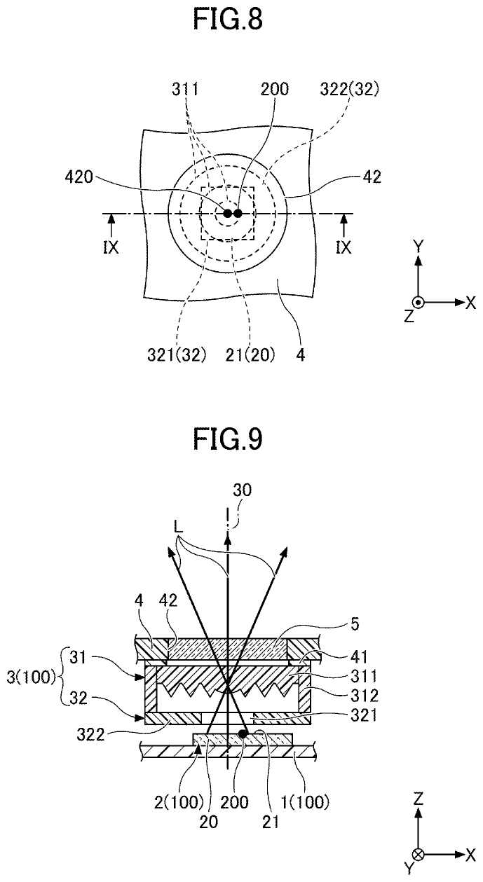

Main effects of the lens unit 3 and the light emitting unit 100 according to the first embodiment will be described with reference to FIG. 6 through FIG. 9. FIG. 6 is a schematic top view illustrating a state in which deviation in position occurs between a light source 2X and a lens optical axis 30X in a light emitting unit 100X according to a comparative example. FIG. 7 is a schematic cross-sectional view of the light emitting unit 100X taken through VII-VII of FIG. 6. FIG. 8 is a schematic top view illustrating a state in which deviation in position occurs between the light source 2 and the lens optical axis 30 in the light emitting unit 100 according to the first embodiment. FIG. 9 is a schematic cross-sectional view of the light emitting unit 100 taken through IX-IX of FIG. 8. In FIG. 6 and FIG. 7, components substantially the same as those of the light emitting unit 100 according to the first embodiment are denoted by the same reference numerals as the components of the light emitting unit 100 of FIG. 1 and FIG. 2, and a duplicate description thereof may be omitted.

As illustrated in FIG. 6 and FIG. 7, the light emitting unit 100X according to the comparative example includes a substrate 1X, the light source 2X, and a lens 3X. The light source 2X includes a light emitting part 20X and is disposed on the substrate 1X. The light emitting part 20X has a light emitting surface 21X. The lens 3X is disposed above the light source 2X.

The lens 3X is fixed to a housing 4 of the smartphone by an adhesive member 41. The housing 4 of the smartphone is spaced apart from the substrate 1X. The lens 3X is fixed to a predetermined position of the housing 4 by the adhesive member 41, and is spaced apart from the substrate 1X. The lens 3X is disposed such that the lens optical axis 30X passes through an opening center 420.

As illustrated in FIG. 6, when the light emitting unit 100X is observed from above a light-transmissive member 5, an observer can visually recognize a portion of the substrate 1X and the light emitting surface 21X of the light source 2X through an opening 42 and the lens 3X. As illustrated in FIG. 7, light emitted from the light source 2X is transmitted through the lens 3X, is then transmitted through the light-transmissive member 5, and is irradiated to a region above the light-transmissive member 5 as irradiation light LX.

If a light emitting unit has a configuration in which a lens is disposed apart from a substrate on which a light source is disposed, deviation in position may occur between the light source and the optical axis of the lens when the light emitting unit is assembled. For example, if the substrate is fixed to the body of a smartphone and the lens is fixed to a housing of the smartphone, which is spaced apart from the substrate, deviation in position may occur between the light source and the optical axis of the lens due to a positional error between the substrate and the body of the smartphone, a positional error between the housing and the body of the smartphone, a positional error between the lens and the housing, and the like.

In the light emitting unit 100X illustrated in FIG. 6 and FIG. 7, a light source center 200X of the light source 2X is deviated toward the +X side from the lens optical axis 30X and the opening center 420. Therefore, as illustrated in FIG. 6, when the light emitting unit 100X is observed from above the light-transmissive member 5, the observer visually recognizes the entire light emitting surface 21X of the light source 2X located at a position where the light source center 200X of the light source 2X is deviated from the opening center 420. In addition, the observer visually recognizes the substrate 1X together with the light emitting surface 21X. If the light source 2X, deviated from the opening center 420, and the substrate 1X are visually recognized, the aesthetic appearance of the light emitting unit 100X would be degraded. Further, in general, when the lens shape is designed, it is assumed that the light source 2X is not deviated from the lens optical axis 30X. Thus, if the light source 2X is deviated from the lens optical axis 30X, the relative position between the entire light emitting surface 21X and the lens optical axis 30X would change. As a result, the irradiation light LX passing through the lens 3X would deviate as illustrated in FIG. 7 as compared to when deviation in position does not occur between the light source 2X and the lens optical axis 30X. As a result, there would be a possibility that the optical characteristics of the irradiation light LX deteriorate and the illuminance distribution of the irradiation light LX is uneven.

In contrast, in the light emitting unit 100 illustrated in FIG. 8 and FIG. 9, a light source center 200 of the light source 2 is deviated in the +X direction from the lens optical axis 30 and the opening center 420. However, the light emitting unit 100 according to the present embodiment allows the observer to visually recognize a portion of the light emitting surface 21 through the first region 321 of the optical member 32, rather than the entire light emitting surface 21 of the light source 2. Therefore, even if the light source center 200 is deviated from the lens optical axis 30 of the lens unit 3 and the opening center 420, the light emitting unit 100 allows the observer to visually recognize a portion of the light emitting surface 21, which is visually recognized through the first region 321, as not being substantially deviated from the opening center 420, as illustrated in FIG. 8. Further, in the present embodiment, by providing the second region 322, the substrate 1 can be hardly visually recognized by the observer. In the present embodiment, even when deviation occurs between the light source 2 and the lens optical axis 30, the light source 2 is visually recognized as not being deviated from the opening center 420, and the substrate 1 is not visually recognized. Accordingly, degradation of the aesthetic appearance of the light emitting unit 100 can be reduced.

Further, in the present embodiment, of the light emitted from the light source 2, light passing mainly through the first region 321 is irradiated as the irradiation light L. Even if deviation occurs between the light source 2 and the lens optical axis 30, the relative position between the first region 321 and the lens optical axis 30 does not substantially change, and thus, the relative position between a portion of the light emitting surface 21 facing the first region 321 and the lens optical axis 30 does not substantially change. Therefore, the irradiation light L transmitted through the Fresnel lens 311 is less likely to deviate. Accordingly, in the present embodiment, deterioration of the optical characteristics of the irradiation light L and unevenness in the illuminance distribution of the irradiation light L can be reduced.

Accordingly, in the present embodiment, the light emitting unit 100 and the lens unit 3, which allow for reducing influence of a deviation between the light source 2 and the lens optical axis 30, can be provided.

### Light Emitting Units According to Modifications of First Embodiment

Light emitting units according to modifications of the first embodiment will be described. In the above-described embodiment and the modifications thereof, the same names and reference numerals denote the same or similar members or components, and a detailed description thereof will be omitted as appropriate. The same applies to other embodiments and modifications thereof, which will be described later.

### First Modification

A light emitting unit according to a first modification of the first embodiment differs from the light emitting unit 100 in that a first region of an optical member of a lens unit is a first light diffusion portion including a light scattering substance.

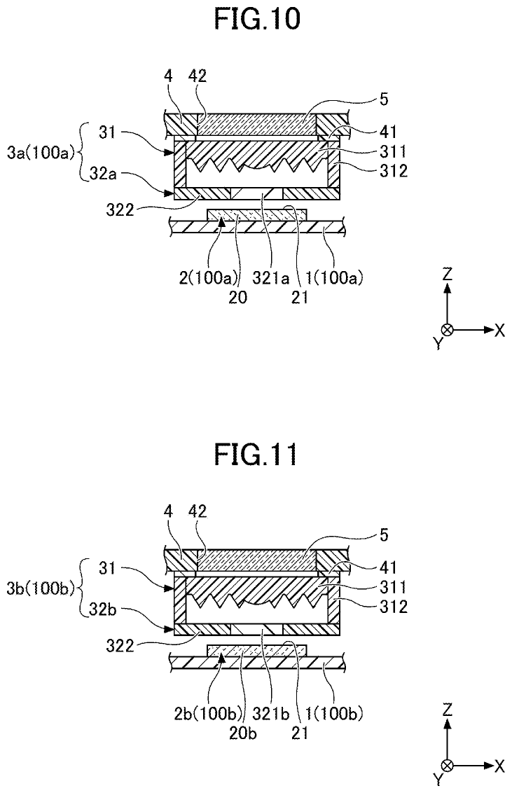

FIG. 10 is a schematic cross-sectional view of a light emitting unit 100a according to the first modification of the first embodiment. The light emitting unit 100a differs from the light emitting unit 100 in that the light emitting unit 100a includes an optical member 32a. The optical member 32a differs from the optical member 32 in that the optical member 32a includes a first region 321a. The first region 321a differs from the first region 321 in having light diffusivity and including a light scattering substance in the first modification. The light scattering substance can be the same as that included in the wavelength conversion member 24.

In the light emitting unit 100a, with the first region 321a including the light scattering substance, influence of illuminance unevenness and color unevenness in the light source 2 can be reduced, and as a result, illuminance unevenness and color unevenness of irradiation light L of the light emitting unit 100a can be reduced. Effects other than the above are substantially the same as those of the light emitting unit 100.

In the present modification, the first region 321 has light diffusivity due to inclusion of the light scattering substance. Therefore, even if the outer edge 21t of the light emitting surface 21 is located inward relative to the outer edge 321t of the first region 321, the outer edge 21t can be hardly visually recognized by the observer. Thus, the outer edge 21t of the light emitting surface 21 is not necessarily located outward relative to the outer edge 321t of the first region 321 in a top view. The light-diffusive first region 321 can be obtained by providing the light scattering substance on one or both of the upper surface and the lower surface of a portion of the optical member, which corresponds to the first region 321, by allowing the light scattering substance to be contained in a portion of the optical member, which corresponds to the first region 321, or by subjecting one or both of the upper surface and the lower surface of a portion of the optical member, which corresponds to the first region 321, to surface treatment such as texturing.

### Second Modification

A light emitting unit according to a second modification of the first embodiment differs from the light emitting unit 100 in that a first region of an optical member of a lens unit is a wavelength conversion portion including a wavelength conversion substance.

FIG. 11 is a schematic cross-sectional view of a light emitting unit 100b according to the second modification of the first embodiment. The light emitting unit 100b differs from the light emitting unit 100 in that the light emitting unit 100b includes a light source 2b and a lens unit 3b. The light source 2b differs from the light source 2 in that the light source 2b includes at least one light emitting part 20b. The light emitting part 20b may be, e.g., the light emitting element 22, and differs from the light emitting part 20 in that the light emitting part 20b does not include at least the wavelength conversion member 24 illustrated in FIG. 3.

The lens unit 3b differs from the lens unit 3 in that the lens unit 3b includes an optical member 32b. The optical member 32b differs from the optical member 32 in that the optical member 32b includes a first region 321b. The first region 321b differs from the first region 321 in that the first region 321b includes a wavelength conversion substance. The wavelength conversion substance can be the same as that included in the above-described wavelength conversion member 24. The light emitting unit 100b can obtain substantially the same effects as those of the above-described light emitting unit 100.

In the present modification, instead of the light emitting part 20b, the first region 321b has a wavelength conversion effect, and the light emitting part 20b is the light emitting element 22. Therefore, the size of the light emitting part 20b can be reduced as compared to the light emitting part 20. Accordingly, the thickness of the light emitting unit 100b can be reduced as compared to the light emitting unit 100. In the present modification, the first region 321b includes the wavelength conversion substance and thus is adapted to diffuse light. Therefore, even if the outer edge 21t of the light emitting surface 21 is located inward relative to the outer edge 321t of the first region 321b, the outer edge 21t can be hardly visually recognized by the observer. Thus, the outer edge 21t of the light emitting surface 21 is not necessarily located outward relative to the outer edge 321t of the first region 321b in a top view. The first region 321b may include both the wavelength conversion substance and the light scattering substance.

### Third Modification

A light emitting unit according to a third modification of the first embodiment differs from the light emitting unit 100 in that a lens of a lens unit has a shape protruding toward the optical member and toward the light-transmissive member 5.

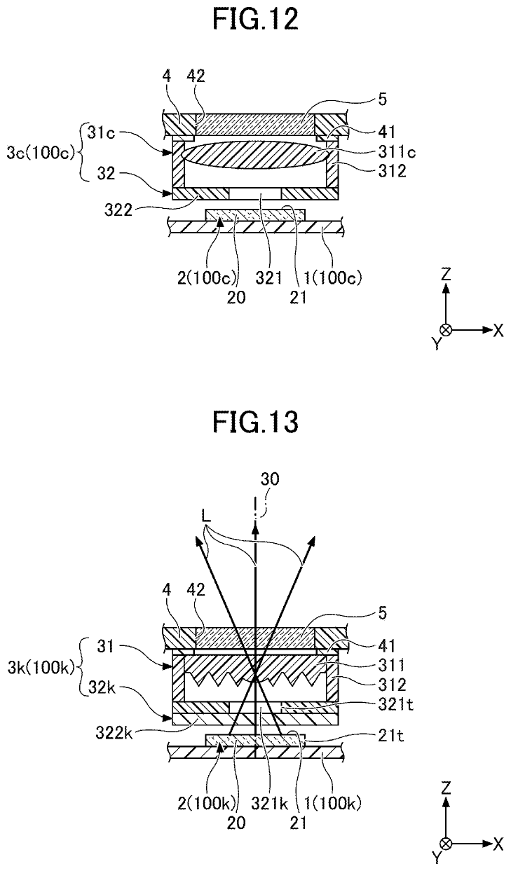

FIG. 12 is a schematic cross-sectional view of a light emitting unit 100c according to the third modification of the first embodiment. The light emitting unit 100c differs from the light emitting unit 100 in that the light emitting unit 100c includes a lens unit 3c. The lens unit 3c differs from the lens unit 3 in that the lens unit 3c includes a lens 31c. The lens 31c differs from the lens 31 in that the lens 31c includes a biconvex lens 311c having a shape protruding toward the optical member 32 and toward the light-transmissive member 5. The biconvex lens 311c has a simple shape, which allows for increasing the light extraction efficiency. The lens 31c does not necessarily include the biconvex lens 311c, and may include any lens having a shape protruding toward the optical member 32, such as a meniscus lens, a plano-convex lens, or the like. The light emitting unit 100c can exhibit substantially the same effects as those of the above-described light emitting unit 100.

### Fourth Modification

A light emitting unit according to a fourth modification of the first embodiment differs from the light emitting unit 100 in that an optical member is composed of two layers.

FIG. 13 is a schematic cross-sectional view of a light emitting unit 100k according to the fourth modification of the first embodiment. The light emitting unit 100k differs from the light emitting unit 100 in that the light emitting unit 100k includes a lens unit 3k. The lens unit 3k differs from the lens unit 3 in that the lens unit 3k includes an optical member 32k. The optical member 32k of the lens unit 3k is composed of two or more layers. In the example of FIG. 13, a first region 321k is formed of one layer, and a second region 322k is formed of two layers. For example, the optical member 32k may be a member in which a substance that reflects, scatters, or absorbs a portion of the light from the light source 2 is disposed on one or both of the upper surface and the lower surface of a plate-shaped member within a region except for the first region 321k. The plate-shaped member includes a light-transmissive resin material, glass, or the like. In this case, the region where the substance that reflects, scatters, or absorbs a portion of the light from the light source 2 is disposed is the second region 322k including a light shielding portion. In FIG. 13, the first region 321k includes a through hole located above the upper surface of the plate-shaped member, which includes a light-transmissive resin material, glass, or the like, and a portion of the plate-shaped member. Thus, the first region 321k is formed of one layer. The through hole is surrounded by the substance that is included in the second region 322k and that reflects, scatters, or absorbs a portion of the light from the light source 2. In the preset modification, the optical member 32k includes the plate-shaped member, so that the optical member 32k can be stable and less likely to bend. Further, the second region 322k can be disposed by applying or printing the substance that reflects, scatters, or absorbs a portion of the light from the light source 2 onto the upper surface or the lower surface of the plate-shaped member, thereby facilitating manufacturing. In the preset modification, the optical member 32k includes the plate-shaped member, which includes a light-transmissive resin material, glass, or the like, the through hole of the first region 321k located on the upper surface of the plate-shaped member, and the light shielding portion of the second region 322k. The light emitting unit 100k can exhibit substantially the same effects as those of the above-described light emitting unit 100.

### Second Embodiment

Next, a light emitting unit according to a second embodiment will be described. The second embodiment differs from the first embodiment mainly in that the light diffusivity of a first region of an optical member of the light emitting unit is higher than that of a second region.

### Example Configuration of Light Emitting Unit 100d

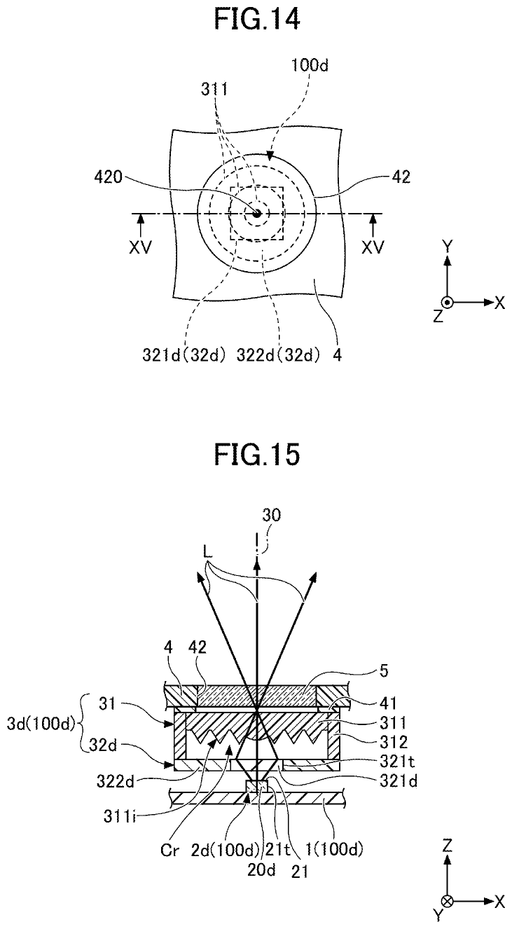

FIG. 14 is a schematic top view illustrating an example of a light emitting unit 100d according to the second embodiment. FIG. 15 is a schematic cross-sectional view of the light emitting unit 100d taken through XV-XV of FIG. 14.

The light emitting unit 100d according to the present embodiment differs from the light emitting unit 100 in that the light emitting unit 100d includes a light source 2d and a lens unit 3d.

The light source 2d differs from the light source 2 in that the light source 2d includes a light emitting part 20d. The light emitting part 20d is disposed on the substrate 1 and has a light emitting surface 21. In the example illustrated in FIG. 15, the light emitting part 20d is mounted on the upper surface (surface on the +Z side) of the substrate 1. The outer shape of the light emitting part 20d in a top view is a substantially rectangular shape. The light emitting part 20d may have an outer shape such as a substantially circular shape, a substantially elliptical shape, or a substantially polygonal shape in a top view. The light source 2d is configured to emit light from the light emitting surface 21 included in the light emitting part 20d toward the lens unit 3d. The number of light emitting parts 20d included in the light source 2d is not limited to one, and one or more light emitting parts 20d may be included.

The lens unit 3d differs from the lens unit 3 in that the lens unit 3d includes an optical member 32d. FIG. 15 illustrates a configuration in which the optical member 32d is composed of one layer. The optical member 32d differs from the optical member 32 in that the optical member 32d includes a first region 321d and a second region 322d. In the present embodiment, the first region 321d includes a first light diffusion portion. The first light diffusion portion includes a light scattering substance. The second region 322d includes a second light diffusion portion or a second light-transmissive portion. The second light diffusion portion includes the light scattering substance. As the light scattering substance included in the first light diffusion portion and the second light diffusion portion, a substance that is the same as that included in the wavelength conversion member 24 in the description above can be used. The second light-transmissive portion does not include the light scattering substance, and transmits the light from the light source 2d. The light diffusivity of the first region 321d is higher than the light diffusivity of the second region 322d. That is, the first region 321d and the second region 322d differ from the first region 321 and the second region 322 in that the light diffusivity of the first region 321d is higher than the light diffusivity of the second region 322d. The second region 322d according to the present embodiment is preferably provided around the entire periphery of the first region 321d. As used herein, the expression “around the entire periphery of the first region 321d” means that the second region 322d is provided around the first region 321d continuously rather than intermittently. From another point of view, the expression “around the entire periphery of the first region 321d” means that the second region 322d is provided adjacent to the outer edge of the first region 321d continuously rather than intermittently.

As illustrated in FIG. 14, when the light emitting unit 100d is observed from above, the observer can visually recognize the first region 321d of the optical member 32d and a portion of the second region 322d of the optical member 32d through the opening 42 and the Fresnel lens 311. When the second region 322d is the second light-transmissive portion, the observer can visually recognize a portion of the substrate 1 through the second light-transmissive portion.

In the present embodiment, an outer edge 21t of a light emitting surface 21 is located inward relative to an outer edge 321t of the first region 321d in a top view. That is, the light emitting part 20d differs from the light emitting part 20 in that the outer edge 21t of the light emitting surface 21 is located inward relative to the outer edge 321t of the first region 321d in a top view. As illustrated in FIG. 15, the light emitted from the light source 2d reaches the first region 321d, which is the first light diffusion portion, is diffused in the first region 321d, and is then transmitted through the Fresnel lens 311. Subsequently, the light transmitted through the Fresnel lens 311 is transmitted through the light-transmissive member 5, and is irradiated toward above the light-transmissive member 5 as irradiation light L.

In the present embodiment, the optical member 32d is fixed to the lens 31 and is spaced apart from the light incident surface 311i of the lens 31. Specifically, as illustrated in FIG. 15, the lens unit 3d has a region Cr, surrounded by the light incident surface 311i of the lens 31, the optical member 32d, and the support member 312. That is, the lens unit 3d has a space between the light incident surface 311i and the optical member 32d. Accordingly, in the lens unit 3d according to the present embodiment, the controllability of incident light by the Fresnel lens 311 is high, as compared to when the optical member are in contact with the light incident surface. The greater the distance between the light incident surface 311i and the optical member 32d, the more uniform the incident angles of light traveling toward the Fresnel lens 311 can be. Accordingly, the lens unit 3 can improve the light controllability, the illuminance ratio, and the light extraction efficiency.

### Effects of First Region 321d and Second Region 322d

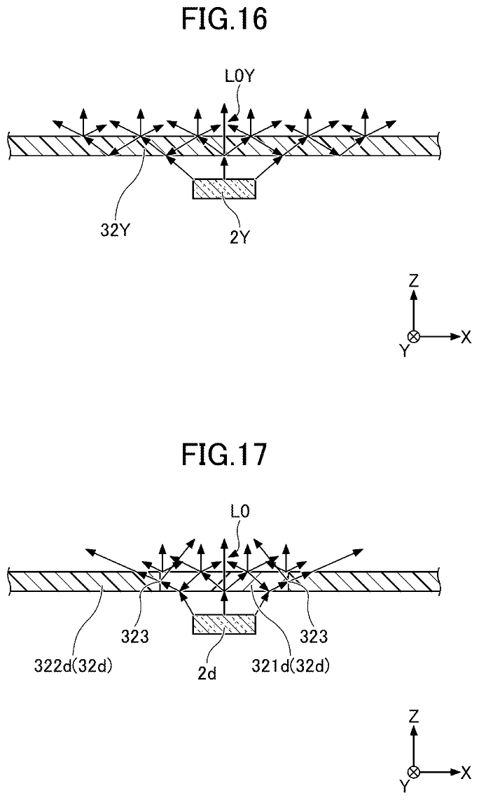

Effects of the first region 321d and the second region 322d of the optical member 32d will be described with reference to FIG. 16 and FIG. 17. FIG. 16 is a schematic cross-sectional view of an optical member 32Y according to a comparative example, and illustrates light propagation in the optical member 32Y. FIG. 17 is a schematic cross-sectional view of the optical member 32d, and illustrates light propagation in the optical member 32d of the light emitting unit 100d.

As illustrated in FIG. 16, according to the comparative example, substantially the entire optical member 32Y includes one or both of a wavelength conversion material and a light scattering material, and the optical member 32Y does not include the first region 321d and the second region 322d. Therefore, a portion of light L0Y emitted from a light source 2Y is transmitted through the optical member 32Y and is irradiated upward, while another portion of the light L0Y propagates inside the optical member 32Y toward the outside of the optical member 32Y, that is, in a direction away from the light source 2Y by reflection at the upper surface (surface on the +Z side) and the lower surface (surface on the −Z side) of the optical member 32Y and also by the scattering effect inside the optical member 32Y. The light propagating inside the optical member 32Y is irradiated upward through the upper surface of the optical member 32Y while propagating toward the outside of the optical member 32Y. As a result, in the optical member 32Y, the light is irradiated upward from substantially the entire optical member 32Y in a top view.

In contrast, as illustrated in FIG. 17, in the optical member 32d according to the present embodiment, a portion of light L0 emitted from the light source 2d is transmitted through the optical member 32d and is emitted upward, while another portion of the light L0 propagates inside the optical member 32d toward the outside of the optical member 32d, that is, in a direction away from the light source 2d by reflection at the upper surface (surface on the +Z side) and the lower surface (surface on the −Z side) of the optical member 32d and also by the scattering effect inside the optical member 32d. The light propagating inside the optical member 32d propagates toward the outside of the optical member 32d, reaches an interface 323 between the first region 321d and the second region 322d, and is reflected by the interface 323 or passes through the interface 323. Of the light propagating inside the optical member 32d toward the outside of the optical member 32d, the amount of light propagating beyond the interface 323 toward the outside of the optical member 32d is reduced due to the reflection at the interface 323. A portion of the light that has passed through the interface 323 enters the second region 322d, but is less likely to serve as a light spot because the light diffusivity of the second region 322d is lower than the light diffusivity of the first region 321d, and the second region 322d has a small diffusion effect. Thus, the light is mainly scattered in the first region 321d having a large scattering effect. As a result, when the lens 31 is observed from the +Z side, of the light emitted from the light source 2 and transmitted through the optical member 32d, light emitted from the first region 321d appears brighter than light emitted from the second region 322d. In addition, the amount of light emitted upward from the first region 321d can be expected to be larger than the amount of light emitted upward from the second region 322d. In this specification, the term “light spot” refers to a point from which light is emitted or from which light is emitted.

### Examples of Manufacturing Methods of Lens Units 3d

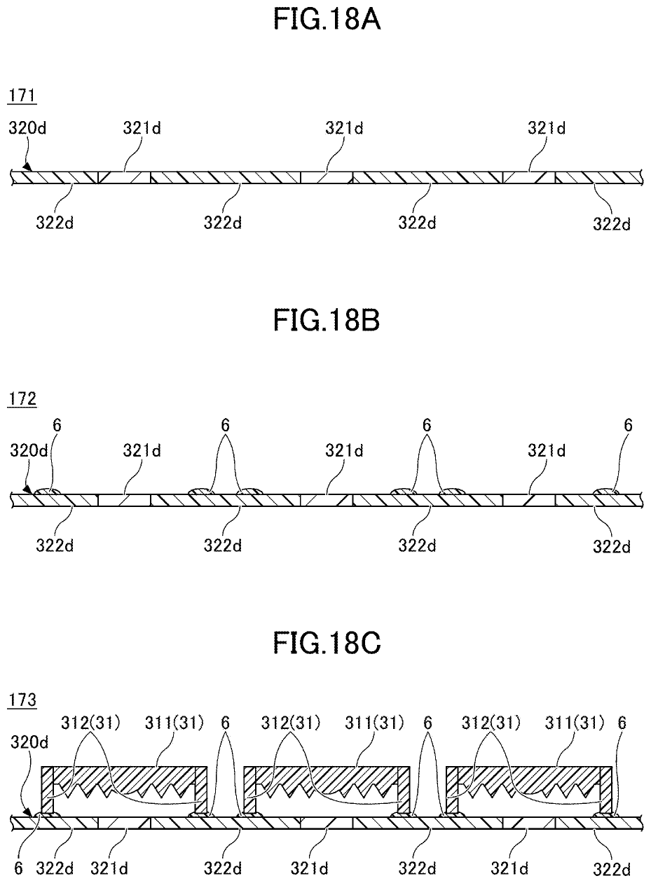

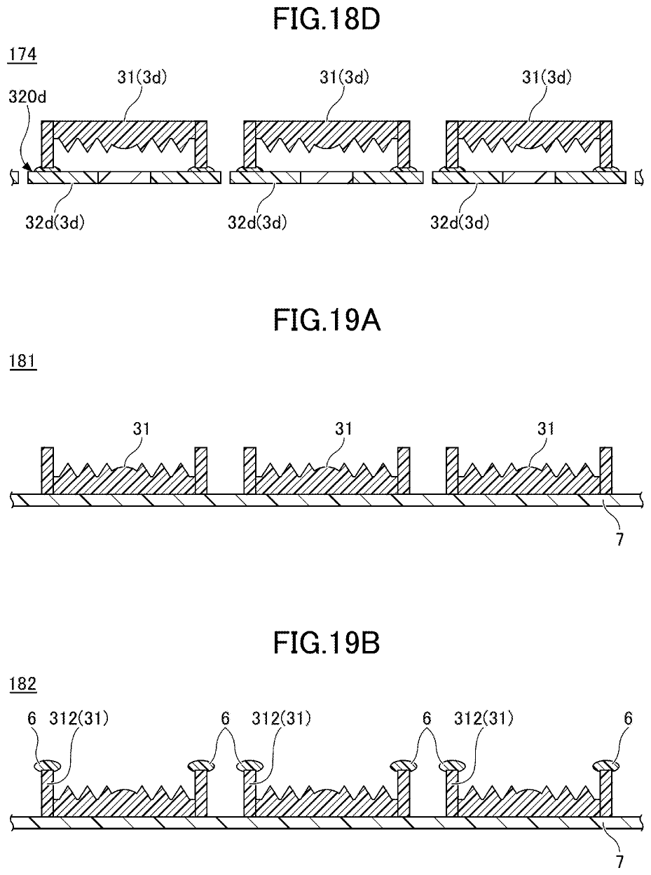

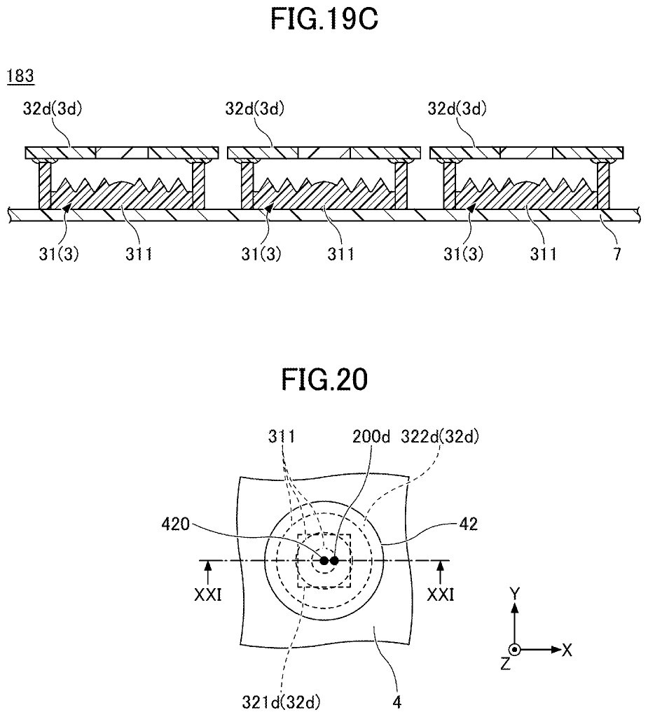

Methods of manufacturing lens units 3d included in light emitting units 100d will be described with reference to FIG. 18A through FIG. 18D and FIG. 19A through FIG. 19C. FIG. 18A through FIG. 18D are diagrams illustrating a first example of a method of manufacturing lens units 3d. FIG. 19A through FIG. 19C are diagrams illustrating a second example of a method of manufacturing lens units 3d.

### First Example

As illustrated in FIG. 18A, FIG. 18B, FIG. 18C, and FIG. 18D, the method of manufacturing lens units 3d according to the first example includes a first step 171, a second step 172, a third step 173, and a fourth step 174.

The first step 171 is a step of providing a base 320d in which a plurality of first regions 321d arranged one-dimensionally or two-dimensionally is formed. In the example illustrated in FIG. 18A through FIG. 18D, three first regions 321d arranged one-dimensionally are formed in the base 320d. Regions other than the first regions 321d in the base 320d correspond to second regions 322d. In the present specification, the expression “providing the base 320d” includes manufacturing the base 320d and obtaining the base 320d by purchasing or the like.

For example, the base 320d is a plate-shaped member including a resin, glass, or the like. Each of the first regions 321d is a first light diffusion portion formed in the base 320d. The regions other than the plurality of first regions 321d in the base 320d include second light diffusion portions or second light-transmissive portions. For example, the base 320d is formed by double molding of resins such that the first regions 321d are formed of a resin having a higher light diffusivity than that of the second regions 322d.

The base 320d may be configured to include a light-transmissive resin, glass, or the like. Alternatively, the base 320d may include a resin glass, a sintered body, or the like having light transmissivity and containing a light scattering substance or a wavelength conversion substance. The first regions 321d of the base 320d may be covered by a diffusion member containing a light scattering substance, such that the light diffusivity of the first region 321d is higher than the light diffusivity of the second regions 322d of the base 320d. Alternatively, the first regions 321d of the base 320d may be subjected to surface treatment such as texturing, such that the light diffusivity of the first region 321d is higher than the light diffusivity of the second regions 322d of the base 320d.

The second step 172 is a step of disposing adhesive members 6 on the base 320d. For example, if each of the adhesive members 6 is a liquid resin, a mechanism or the like that can discharge the adhesive members 6 is used to apply the adhesive members 6 onto a plurality of predetermined positions of the second regions 322d of the base 320d. Each of the adhesive members 6 may be a double-sided tape.

The third step 173 is a step of fixing lenses 31 to the base 320d. In the third step 173, before hardening of the resin, serving as the adhesive members 6 and applied to the second regions 322d of the base 320d, is completed, the lenses 31 are disposed on the base 320d such that support members 312 of the lenses 31 contact the adhesive members 6. The lenses 31 are disposed on the base 320d such that each of the lenses 31 corresponds to a respective one of the first regions 321d and that the center of each of the first regions 321d substantially faces the center of a respective one of Fresnel lenses 311. After the lenses 31 are disposed on the base 320d, hardening of the resin serving as the adhesive members 6 are completed, so that the lenses 31 are fixed to the base 320d. For the adhesive members 6, an air-setting member or a member that sets by being irradiated with energy rays such as heat or ultraviolet light may be used.

The fourth step 174 is a step of cutting into a plurality of lens units 3d from the base 320d by cutting the base 320d. Regions of the base 320d that are located outward of the lenses 31 are cut into the plurality of lens units 3d from the base 320d by dicing, laser processing, or the like. In the example illustrated in FIG. 18A through FIG. 18D, three lens units 3d are obtained by cutting.

In this manner, the lens units 3d can be manufactured by the manufacturing method according to the first example.

### Second Example

As illustrated in FIG. 19A, FIG. 19B, and FIG. 19C, the method of manufacturing lens units 3d according to the second example includes a first step 181, a second step 182, and a third step 183.

The first step 181 is a step of mounting a plurality of lenses 31 on a base 7. The lenses 31 are mounted on the base 7 such that the light exit side of each of the lenses 31, specifically, the light exit surface of each of Fresnel lenses 311 faces the base 7. In the example illustrated in FIG. 19A through FIG. 19C, three lenses 31 are arranged one-dimensionally on the base 7.

The second step 182 is a step of disposing adhesive members 6 on support members 312 of the plurality of lenses 31. The adhesive members 6 are disposed on end portions of the support members 312, which are located on the light incident side of the lenses 31. That is, the adhesive members 6 are disposed on the -Z side of the support members 312. For example, when each of the adhesive members 6 is a liquid resin, a mechanism or the like that can discharge the adhesive members 6 is used to apply the adhesive members 6. Each of the adhesive members 6 may be a double-sided tape.

The third step 183 is a step of fixing optical members 32d to the lenses 31.

In the third step 183, before hardening of the resin, serving as the adhesive members 6 and applied to the support members 312, is completed, the optical members 32d are disposed on the lenses 31 such that the optical members 32d are in contact with the adhesive members 6. Each of the optical members 32d are disposed on a respective one of the lenses 31 such that the center of each of the Fresnel lenses 311 faces the center of a respective one of the first regions 321d. After the optical members 32d are disposed, hardening of the resin serving as the adhesive members 6 are completed, so that the optical members 32d are fixed to the respective lenses 31. Subsequently, the lenses 31 are separated from the base 7 to obtain lens units 3d.

In this manner, the lens units 3d can be manufactured by the manufacturing method according to the second example.

### Main Effects of Lens Unit 3D and Light Emitting Unit 100D

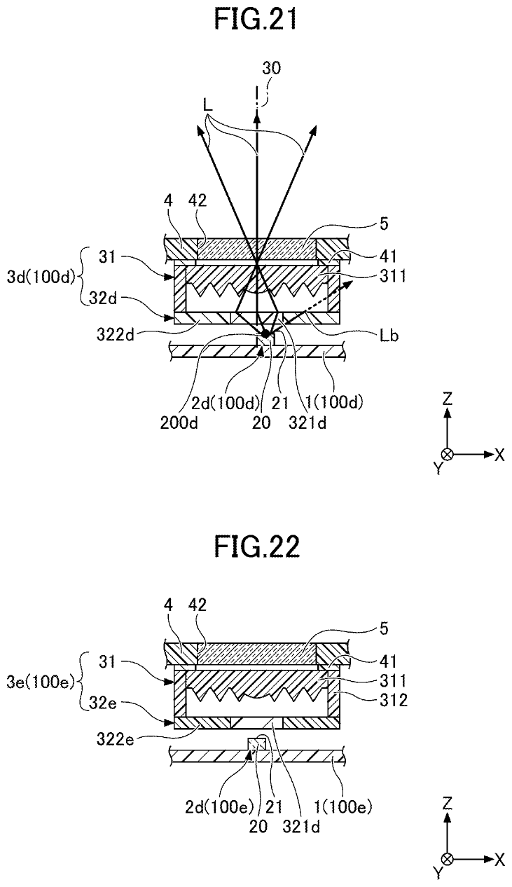

Main effects of the lens unit 3d and the light emitting unit 100d according to the second embodiment will be described with reference to FIG. 20 and FIG. 21. FIG. 20 is a schematic top view illustrating a state in which deviation occurs between the light source 2d and the lens optical axis 30 in the light emitting unit 100d according to the second embodiment. FIG. 21 is a schematic cross-sectional view of the light emitting unit 100d taken through XXI-XXI of FIG. 20.

As illustrated in FIG. 20 and FIG. 21, a light source center 200d of the light source 2d is deviated toward the +X side from the lens optical axis 30 and the opening center 420. However, the light emitting unit 100d according to the present embodiment allows the observer to visually recognize the first region 321d of the optical member 32d and a portion of the second region 322d of the optical member 32d through the opening 42 and the Fresnel lens 311. Further, in the present embodiment, the light from the light source 2d is transmitted mainly through the first region 321d, is diffused in the first region 321d, and is irradiated upward. The light diffused in the first region 321d is irradiate upward from substantially the entire first region 321d in a top view. With the light-diffusive first region 321d of the optical member 32d, the light source 2d can be hardly visually recognized by the observer when the light emitting unit 100d is viewed from above. Accordingly, in the present embodiment, even if the light source center 200d is deviated from the lens optical axis 30 and the opening center 420, the observer can visually recognize the first region 321d as being not substantially deviated from the opening center 420 while hardly visually recognizing the light source 2d, as illustrated in FIG. 20. Accordingly, in the present embodiment, degradation of the aesthetic appearance of the light emitting unit 100d can be reduced even when deviation in position occurs between the light source 2d and the lens optical axis 30. Further, in FIG. 21, light Lb passing through the second region 322d directly passes through the second region 322d. Therefore, the amount of light incident onto the Fresnel lens 311 is reduced, and thus, the optical characteristics of the light emitting unit 100d is not greatly affected. As a result, influence of a deviation from the optical axis can be reduced.

Further, in the present embodiment, as illustrated in FIG. 21, of the light emitted from the light source 2d, light transmitted mainly through the first region 321d is irradiated as irradiation light L. Even if deviation in position occurs between the light source 2d and the lens optical axis 30, the light emitted from the light source 2d is diffused mainly in the first region 321d and is emitted from the first region 321d in a mixed state. Therefore, the relative position between the first region 321d and the lens optical axis 30 does not substantially change. Since the relative position between the first region 321d and the lens optical axis 30 does not substantially change, the irradiation light L transmitted through the Fresnel lens 311 is less likely to deviate.

Accordingly, in the present embodiment, deterioration of the optical characteristics of the irradiation light L and unevenness in the illuminance distribution of the irradiation light L can be reduced.

Accordingly, in the present embodiment, the light emitting unit 100d and the lens unit 3d, capable of reducing influence of a deviation between the light source 2d and the lens optical axis 30, can be provided. Further, in the present embodiment, the light from the light source 2d is not shielded by a light shielding portion or the like.

Thus, a decrease in the irradiation efficiency of the light emitting unit 100d can be avoided. In the present embodiment, when the second region 322d of the optical member 32d has light diffusivity, in other words, when the second region 322d is the second light diffusion portion, the outer edge 21t of the light emitting surface 21 is not necessarily located inward relative to the outer edge 321t of the first region 321 in a top view. Even when the outer edge 21t of the light emitting surface 21 is located slightly outward relative to the outer edge 321t of the first region 321, substantially the same effects as those described above can be obtained.

### Light Emitting Units According to Modifications of Second Embodiment

### First Modification

A light emitting unit according to a first modification of the second embodiment differs from the light emitting unit 100d, in that a second region of an optical member of a lens unit is composed of either a white resin containing a light scattering substance or a black resin containing a light absorbing substance.

FIG. 22 is a schematic cross-sectional view of a light emitting unit 100e according to the first modification of the second embodiment. The light emitting unit 100e differs from the light emitting unit 100d in that the light emitting unit 100e includes an optical member 32e. The optical member 32e differs from the optical member 32d in that the optical member 32e includes a second region 322e. The second region 322e differs from the second region 322d in that the second region 322e is composed of either a white resin containing a light scattering substance such as titanium oxide or a black resin containing a light absorbing substance such as carbon black.

Since the light emitting unit 100e includes the second region 322e, influence of illuminance unevenness and color unevenness in the light source 2d can be reduced, and as a result, illuminance unevenness and color unevenness of irradiation light L of the light emitting unit 100e can be reduced. Specifically, when the second region 322e is the white resin, light emitted from the light source 2d is reflected by the second region 322e and the reflected light passes through the first region 321, thereby improving the light extraction of the light emitting unit 100e. When the second region 322e is the black resin, the second region 322e absorbs the light emitted from the light source 2d, and thus, stray light can be reduced and the light controllability is high. Effects other than the above are substantially the same as those of the light emitting unit 100d.

### Second Modification

A light emitting unit according to a second modification of the second embodiment differs from the light emitting unit 100d, in that a first region of an optical member of a lens unit is a wavelength conversion portion including a wavelength conversion substance.

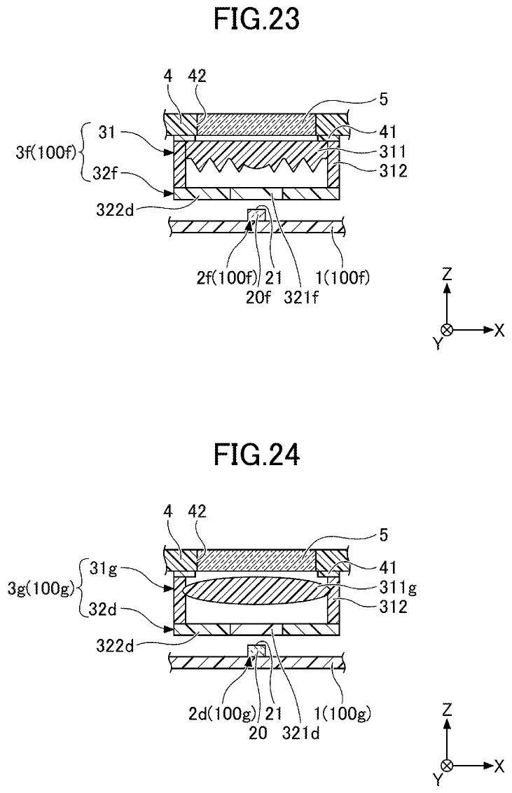

FIG. 23 is a schematic cross-sectional view of a light emitting unit 100f according to the second modification of the second embodiment. The light emitting unit 100f differs from the light emitting unit 100d in that the light emitting unit 100f includes a light source 2f and a lens unit 3f. The light source 2f differs from the light source 2d in that the light source 2f includes a light emitting part 20f. The light emitting part 20f may be, e.g., the light emitting element 22, and differs from the light emitting part 20d in that the light emitting part 20f does not include at least the wavelength conversion member 24 illustrated in FIG. 3.

The lens unit 3f differs from the lens unit 3d in that the lens unit 3f includes an optical member 32f. The optical member 32f differs from the optical member 32d in that the optical member 32f includes a first region 321f. The first region 321f differs from the first region 321d in that the first region 321f includes a wavelength conversion substance. As the wavelength conversion substance, a substance that is the same as that included in the above-described wavelength conversion member 24 can be used. The light emitting unit 100f can exhibit substantially the same effects as those of the above-described light emitting unit 100d.

In the present modification, instead of the light emitting part 20f, the first region 321f has a wavelength conversion effect, and the light emitting part 20f is the light emitting element 22. Therefore, the size of the light emitting part 20f can be reduced as compared to the light emitting part 20d. Accordingly, the thickness of the light emitting unit 100f can be reduced as compared to the light emitting unit 100d. In the present modification, the first region 321f has light diffusivity by including the wavelength conversion substance. Thus, even if the outer edge 21t of the light emitting surface 21 is located inward relative to the outer edge 321t of the first region 321f, the outer edge 21t can be hardly seen by the observer. Therefore, the outer edge 21t of the light emitting surface 21 is not necessarily located outward relative to the outer edge 321t of the first region 321f in a top view. The first region 321f may include both the wavelength conversion substance and the light scattering substance.

### Third Modification

A light emitting unit according to a third modification of the second embodiment differs from the light emitting unit 100d, in that a lens of a lens unit has a shape protruding toward the optical member and toward the light-transmissive member 5.

FIG. 24 is a schematic cross-sectional view of a light emitting unit 100g according to the third modification of the second embodiment. The light emitting unit 100g differs from the light emitting unit 100d in that the light emitting unit 100g includes a lens unit 3g. The lens unit 3g differs from the lens unit 3d in that the lens unit 3g includes a lens 31g. The lens 31g differs from the lens 31 in that the lens 31g includes a biconvex lens 311g having a shape protruding toward the optical member 32d and toward the light-transmissive member 5. The lens 31g does not necessarily include the biconvex lens 311g, and may include any lens having a shape protruding toward the optical member 32d, such as a meniscus lens, a plano-convex lens, or the like. The light emitting unit 100g can exhibit substantially the same effects as those of the above-described light emitting unit 100d.

### Fourth Modification

A light emitting unit according to a fourth modification of the second embodiment differs from the light emitting unit 100d in that an optical member is composed of two layers.

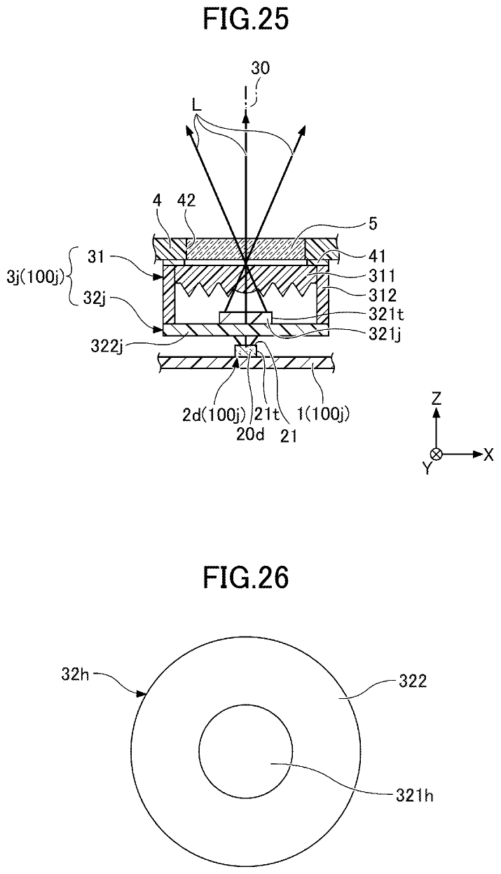

FIG. 25 is a schematic cross-sectional view of a light emitting unit 100j according to the fourth modification of the second embodiment. An optical member 32j of a lens unit 3j may be composed of two or more layers. In FIG. 25, a first region 321j is the second layer, and a second region 322j is the first layer. For example, the optical member 32j may be a member in which a substance that reflects, scatters, or absorbs a portion of the light from the light source 2d on one or both of the upper surface and the lower surface of a plate-shaped member is disposed within a region except for the second region 322j. The plate-shaped member includes a light-transmissive resin material, glass, or the like. In this case, the region where the substance that reflects or scatters a portion of the light from the light source 2d is disposed is the first region 321j. As long as the light diffusivity of the first region 321j is higher than the light diffusivity of the second region 322j, the substance that reflects or scatters a portion of the light from the light source 2d may be disposed on the plate-shaped member that includes a light-transmissive resin material, glass, or the like. The substance that reflects or scatters a portion of the light from the light source 2d is one or both of the wavelength conversion substance and the light scattering substance described above. In the preset modification, since the optical member 32j includes the plate-shaped member, the optical member 32j can become stable and less likely to bend. Further, the first region 321j can be disposed by applying or printing the substance that reflects or scatters a portion of the light from the light source 2d onto the upper surface or the lower surface of the plate-shaped member, thereby facilitating manufacturing. The light emitting unit 100j can obtain substantially the same effects as those of the above-described light emitting unit 100d.

Although the embodiments have been described in detail above, the present disclosure is not limited to the above-described embodiments, and various modifications and substitutions can be made to the above-described embodiments without departing from the scope described in the claims.

For example, the outer shape of a first region of an optical member in a top view may be a ring shape. FIG. 26 is a schematic top view of an optical member 32h according to a first variation. The optical member 32h differs from the optical member 32 in that the optical member 32h includes a first region 321h. The first region 321h differs from the first region 321 in having an annular outer shape. With the annular outer shape of the first region 321h of the optical member 32h in a top view, e.g., when the lens includes a Fresnel lens, the outer shape of the first region 321h can conform to the shape of the Fresnel lens having concentric projections.

Therefore, the aesthetic appearance can be expected to be improved. In a case where the light emitting units according to the first embodiment, the first through fourth modifications of the first embodiment, the second embodiment, and the first through fourth modifications of the second embodiment described above include the optical member 32h, substantially the same effects as those described above can be obtained.

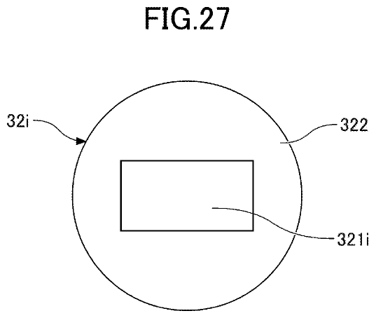

Further, for example, the aspect ratio of a first region of an optical member in a top view may be 2.4 or less. FIG. 27 is a schematic top view of an optical member 32i according to a second variation. The optical member 32i differs from the optical member 32 in that the optical member 32i has a first region 321i. The first region 321i differs from the first region 321 in that the aspect ratio of the first region 321i is 2.4 or less (that is, the first region 321i has a rectangular shape). The aspect ratio of the first region of the optical member in a top view is preferably 1 or more and 2.4 or less. By setting the aspect ratio to 1 or more and 2.4 or less, a region irradiated with light by a light emitting unit can be adjusted according to the aspect ratio of a camera or the aspect ratio of a screen of a smartphone. In a case where the light emitting units according to the first embodiment, the first through fourth modifications of the first embodiment, the second embodiment, and the first through fourth modifications of the second embodiment described above include the optical member 32i, substantially the same effects as those described above can be obtained.

The numbers such as ordinal numbers and quantities used in the description of the embodiments are all exemplified to specifically describe the technique of the present disclosure, and the present disclosure is not limited to the exemplified numbers. In addition, the connection relationship between the components is illustrated for specifically describing the technique of the present disclosure, and the connection relationship for implementing the functions of the present disclosure is not limited thereto.

The light emitting units according to the present disclosure can reduce stray light on irradiation surfaces. Therefore, the light emitting units according to the present disclosure can be suitably used for lighting, camera flashes, vehicle headlights, and the like. However, the application of the light emitting units according to the present disclosure is not limited to these applications.

According to an embodiment of the present disclosure, a light emitting unit and a lens unit, capable of reducing influence of a deviation between a light source and the optical axis of a lens when the lens is disposed apart from a substrate on which the light source is disposed, can be provided.

What is claimed is:

1. A light emitting unit comprising:
a substrate;
a light source disposed on the substrate and having a light emitting surface; and
a lens unit comprising:
a lens disposed above the light source, and
an optical member fixed to the lens and disposed between the light source and the lens, the optical member comprising:
a first region facing the light emitting surface, and
a second region provided around the first region, wherein:
a light transmittance of the first region is higher than a light transmittance of the second region, and
the lens unit is not fixed to the substrate.

2. The light emitting unit according to claim 1, wherein:
the first region comprises any one of a through hole, a first light-transmissive portion, a wavelength conversion portion, or a first light diffusion portion,
the second region comprises a light shielding portion, and
in a top view, an outer edge of the light emitting surface is located outward of an outer edge of the first region.

3. The light emitting unit according to claim 1, wherein a distance between the light source and the optical member is 0 mm or more and 2 mm or less.

4. The light emitting unit according to claim 1, wherein:
the light source comprises at least one light emitting part, the light emitting part comprising:
a light emitting element,
a wavelength conversion member disposed on the light emitting element, and
a light shielding member covering lateral surfaces of the light emitting element and a bottom surface of the wavelength conversion member.

5. A light emitting unit comprising:
a substrate;
a light source disposed on the substrate and having a light emitting surface; and
a lens unit comprising:
a lens disposed above the light source, and
an optical member fixed to the lens and disposed between the light source and the lens, the optical member comprising:
a first region facing the light emitting surface, and
a second region provided around the first region, wherein:
a light diffusivity of the first region is higher than a light diffusivity of the second region, and
the lens unit is spaced apart from the substrate.

6. The light emitting unit according to claim 5, wherein:
the first region comprises a first light diffusion portion or a wavelength conversion portion,
the second region comprises a second light diffusion portion or a second light-transmissive portion, and
in a top view, an outer edge of the light emitting surface is located inward of an outer edge of the first region.

7. The light emitting unit according to claim 5, wherein a distance between the light source and the optical member is 0 mm or more and 2 mm or less.

8. The light emitting unit according to claim 5, wherein:
the light source comprises at least one light emitting part, the light emitting part comprising:
a light emitting element,
a wavelength conversion member disposed on the light emitting element, and
a light shielding member covering lateral surfaces of the light emitting element and a bottom surface of the wavelength conversion member.

9. A lens unit to be fixed to a housing of an image capturing device, the lens unit comprising:
a lens; and
an optical member fixed to the lens, the optical member comprising:
a first region, and
a second region provided around the first region, wherein:
a light transmittance of the first region is higher than a light transmittance of the second region, and
the lens has a shape protruding toward the optical member.

10. The lens unit according to claim 9, wherein:
the first region comprises any one of a through hole, a first light-transmissive portion, a wavelength conversion portion, or a first light diffusion portion,
the second region comprises a light shielding portion, and
the light shielding portion is formed of a white resin containing a light scattering substance.

11. The lens unit according to claim 9, wherein, in a top view, an outer shape of the first region is an annular shape.

12. The lens unit according to claim 9, wherein, in a top view, an aspect ratio of the first region is 2.4 or less.

13. The lens unit according to claim 9, wherein the lens comprises a Fresnel lens.

14. A lens unit comprising:
a lens; and
an optical member fixed to the lens, the optical member comprising:
a first region, and
a second region provided around an entire periphery of the first region, wherein:
a light diffusivity of the first region is higher than a light diffusivity of the second region.

15. The lens unit according to claim 14, wherein:
the first region comprises a first light diffusion portion or a wavelength conversion portion, and
the second region comprises a second light diffusion portion or a second light-transmissive portion.

16. The lens unit according to claim 14, wherein:
the second region is formed of either a white resin containing a light scattering substance or a black resin containing a light absorbing substance.

17. The lens unit according to claim 14, wherein the lens has a shape protruding toward the optical member.

18. The lens unit according to claim 14, wherein, in a top view, an outer shape of the first region is an annular shape.

19. The lens unit according to claim 14, wherein, in a top view, an aspect ratio of the first region is 2.4 or less.

20. The lens unit according to claim 14, wherein the lens comprises a Fresnel lens.
